(19) United States
(12) Patent Application Publication
(10) Pub. No.: US 2013/0211754 A1
(43) Pub. Date: Aug. 15, 2013

(54) Extensible Power Meter

(71) Applicants: Stephen Edmund Herzog, Hillsboro, OR (US); Steven M. Lewis, Beaverton, OR (US); Andrew B. Levy, West Linn, OR (US)

(72) Inventors: Stephen Edmund Herzog, Hillsboro, OR (US); Steven M. Lewis, Beaverton, OR (US); Andrew B. Levy, West Linn, OR (US)

(73) Assignee: LEVITON MANUFACTURING CO., INC., Melville, NY (US)

(21) Appl. No.: 13/371,073

(22) Filed: Feb. 10, 2012

(51) Int. Cl. G01R 21/00; G06F 19/00

(52) U.S. Cl. 702/62

(57) ABSTRACT

An embodiment of an electronic assembly may include a power meter, a network interface, and a processing unit to log data received from the power meter and upload the data through the network interface, wherein the processing unit operates an extensible run-time environment for add-on software modules. Another embodiment of an electronic assembly may include a meter interface, a network interface, and a processing unit to perform power calculations on signals received at the meter interface, log meter data from the power calculations, and upload the meter data through the network interface, wherein the processing unit operates an extensible run-time environment for add-on software modules.

### BACKGROUND

Networked power meters are used to provide remote power metering of electrical apparatus through a communication network for purposes of billing, sub-metering, power quality monitoring, building automation, building energy management, etc. A networked power meter typically includes a measurement interface, a metering processor, and a network interface. The measurement interface enables the power meter to be connected to an electrical apparatus to measure the power consumed or generated by the apparatus. The metering processor calculates values such as power in Kilowatts (KW), energy consumption in Kilowatt hours (KWH), and power factor (PF). The network interface enables the output from the processing circuitry to be transmitted through a communication network to an extensible power meter, building automation controller, or other system for further processing, analysis, etc.

### BRIEF DESCRIPTION OF THE DRAWINGS

FIG. 1 illustrates an embodiment of extensible power meter according to some inventive principles of this patent disclosure.

FIG. 2 illustrates an embodiment of extensible power meter according to some inventive principles of this patent disclosure.

FIG. 3 illustrates an embodiment of a software platform suitable for use with an extensible power meter according to some inventive principles of this patent disclosure.

FIG. 4 illustrates another embodiment of an extensible power meter according to some inventive principles of this patent disclosure.

FIG. 5 illustrates an embodiment of an extensible power meter configured to provide secure anti-tamper metering according to some inventive principles of this patent disclosure.

FIG. 6 illustrates an embodiment of a power generation system utilizing cellular communication technology according to some inventive principles of this patent disclosure.

FIG. 7 illustrates an embodiment of a system with an extensible power meter arranged for comparison, verification, etc., of readings from multiple power meters according to some inventive principles of this patent disclosure.

FIG. 8 illustrates an exemplary embodiment of an extensible power meter according to some inventive principles of this patent disclosure.

FIG. 9 illustrates another exemplary embodiment of an extensible power meter according to some inventive principles of this patent disclosure.

FIG. 10 illustrates another exemplary embodiment of an extensible power meter according to some inventive principles of this patent disclosure.

### DETAILED DESCRIPTION

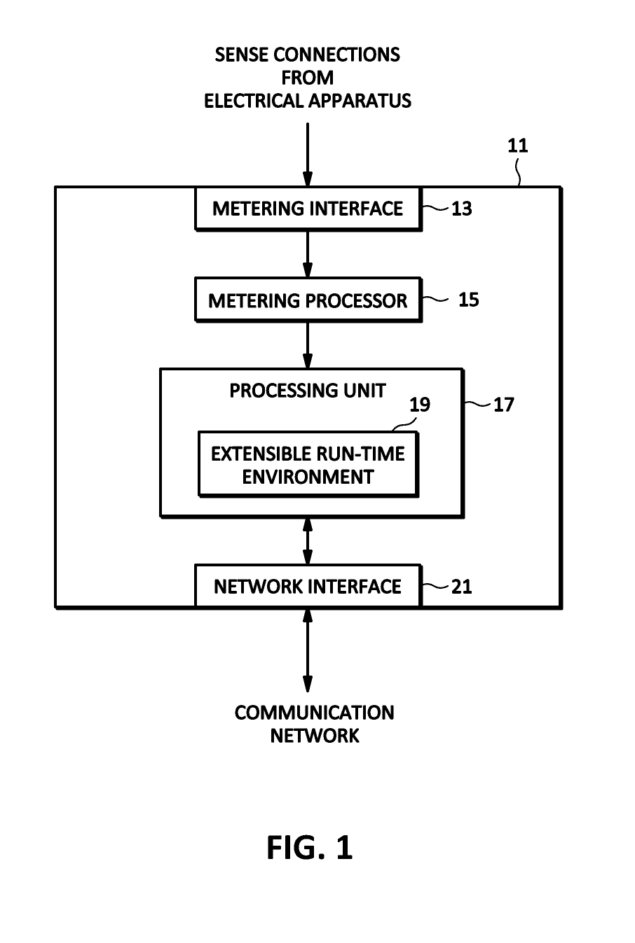

FIG. 1 illustrates an embodiment of an extensible power meter according to some inventive principles of this patent disclosure. The embodiment of FIG. 1 includes an electronic assembly 11 having having a metering interface 13, a metering processor 15, a processing unit 17 that operates an extensible run-time environment 19 for running add-on software modules, and a network interface 21.

The metering interface 13 may include any suitable apparatus to convert voltage and current sense signals from the electrical apparatus being monitored to a form that can be used by the metering processor 15. For example, if the metering processor 15 includes all of the circuitry needed to receive high-voltage and current sense inputs directly, the metering interface 13 may include nothing more than one or more terminal strips for making connections to the metering processor 15. As another example, if the metering processor only has A/D converters capable of receiving 0-3.3 volt or 0-5 volt analog inputs, the metering interface 13 may include circuitry having resistive dividers, rectifiers, amplifiers, capacitors, etc., to convert the signals from high-voltage sense connections, current transformers, Hall-effect sensor, etc., to a form that can be read by the A/D converters on the metering processor 15. The metering processor 15 may be implemented with analog and/or digital hardware, software, firmware, etc., or any suitable combination thereof.

The processing unit 17 enables data from the metering processor to be logged and uploaded through the network interface 21. The processing unit 17 implements an extensible run-time environment 19 for running add-on software modules that enable the system to implement different types of functionality to accommodate any type of application environment as explained in more detail below.

The metering processor 15 and processing unit 17 may be implemented separately as shown in FIG. 1, or they may be combined into a single processor. Likewise, the network interface 21 may be separate from, or combined with, the processing unit 17.

The network interface 21 may be implemented with any suitable hardware and protocols. For example, in some embodiments, the network interface may be implemented as an industrial network interface that is constructed to accommodate relatively low-level hardware and protocols of the types commonly used in real-time control systems as described in more detail below. In other embodiments, the network interface 21 may be implemented as a more general purpose computer network interface with relatively high-level hardware and protocols of the types commonly used to interconnect general purpose computers as described in more detail below. Yet other embodiments may include two or more network interfaces of various types.

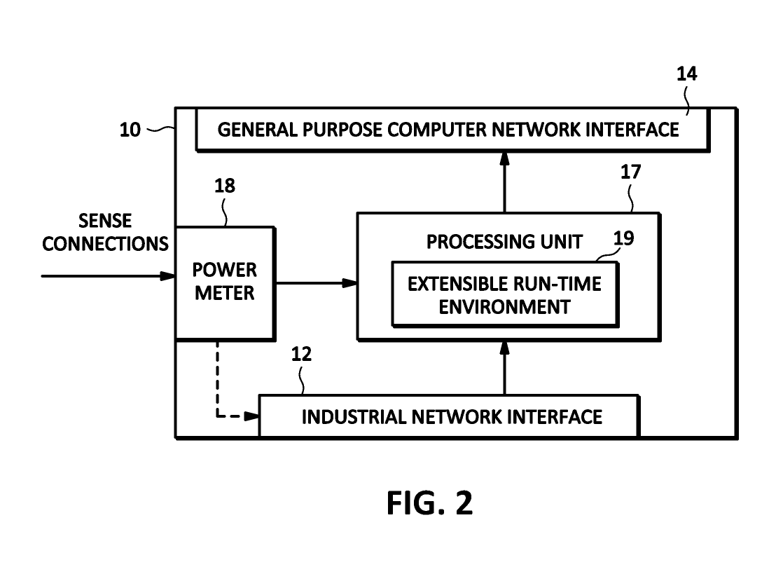

FIG. 2 illustrates another embodiment of an extensible power meter according to some inventive principles of this patent disclosure. The embodiment of FIG. 2 includes an electronic assembly 10 having an industrial network interface 12 to couple the electronic assembly to industrial devices, a general purpose computer network interface 14, a processing unit 17 to log data received from the power meter 18 and upload the data through the general purpose computer network interface, and a power meter 18 coupled to the processing unit. The power meter 18 integrates a metering interface and a metering processor into a complete power meter. The processing unit 17 may also include functionality to log data from the industrial devices through the industrial network interface and upload the data from the power meter 18 through the general purpose computer network interface 14. Thus, the embodiment of FIG. 2 may also function as a data acquisition server (DAS) to log data from industrial devices such as power meters, flow meters, temperature, and humidity and other environmental sensors, as well as power generators and converters. At predetermined time intervals, the system may upload the logged data to a centralized location such as a building automation system for processing.

The processing unit 17 implements an extensible run-time environment 19 for running add-on software modules that enable the system to implement different types of functionality to accommodate any type of application environment as explained in more detail below.

The industrial network interface 12 may be constructed to accommodate relatively low-level hardware and protocols of the types commonly used in real-time control systems to interconnect sensors, actuators, controllers, and other industrial devices for factory automation, process control applications, building energy controls, etc. Some examples include an RS485 hardware layer running the Modbus, Profibus or DMX512 protocols; an RS422 hardware layer running Profibus or Field bus; an RS485 or RS232 hardware layer running the Fronius Interface Protocol (IFP), etc. Some other examples include Control Area Network (CAN), LonWorks, etc. The industrial network may also include translators such as ModHopper™ wireless transceivers which may be used to interface wireless mesh devices to a Modbus wired network. Yet another example is a Modbus variant known as Modbus-TCP which is essentially the Modbus protocol transmitted over a network using a TCP/IP stack.

The power meter 18 may be realized with any suitable implementation details. For example, the meter may measure DC and/or AC power including single-phase power, three-phase power, etc. It may be line powered or battery powered, it may have a dedicated power supply, or it may share a power supply with the rest of the electronic assembly 10. The power meter 18 may be implemented as a relatively high accuracy meter suitable for billing purposes or verification of utility meters, or it may be implemented with less accurate, lower cost circuitry for other monitoring purposes.

The power meter 18 may be interfaced directly to the processing unit 17 as shown with the solid line in FIG. 2, or it may be interfaced in any other suitable manner. For example, the dashed line in FIG. 2 illustrates that the power meter may be interfaced to the processing unit through the industrial network interface 12.

The general purpose computer network interface 14 may be implemented with relatively high-level hardware and protocols of the types commonly used to interconnect general purpose computers in wide-area networks (WANs), local-area networks (LANs), the Internet, etc. Examples include internet protocol (IP) running on Ethernet, WiFi, etc.

Any of the components of the embodiment of FIG. 2 may be implemented with analog and/or digital hardware, software, firmware or any suitable combination thereof. The components may be separate or integrated in any suitable manner. For example, the processing unit 17 may be implemented as a single-board computer built around a microcontroller having dedicated peripheral integrated circuits (ICs) for the industrial network interface 12, the general purpose computer network interface 14, and the power meter 18. Alternatively, some or all of the interfaces 12 and 14 and meter 18 may be integrated directly into the microcontroller.

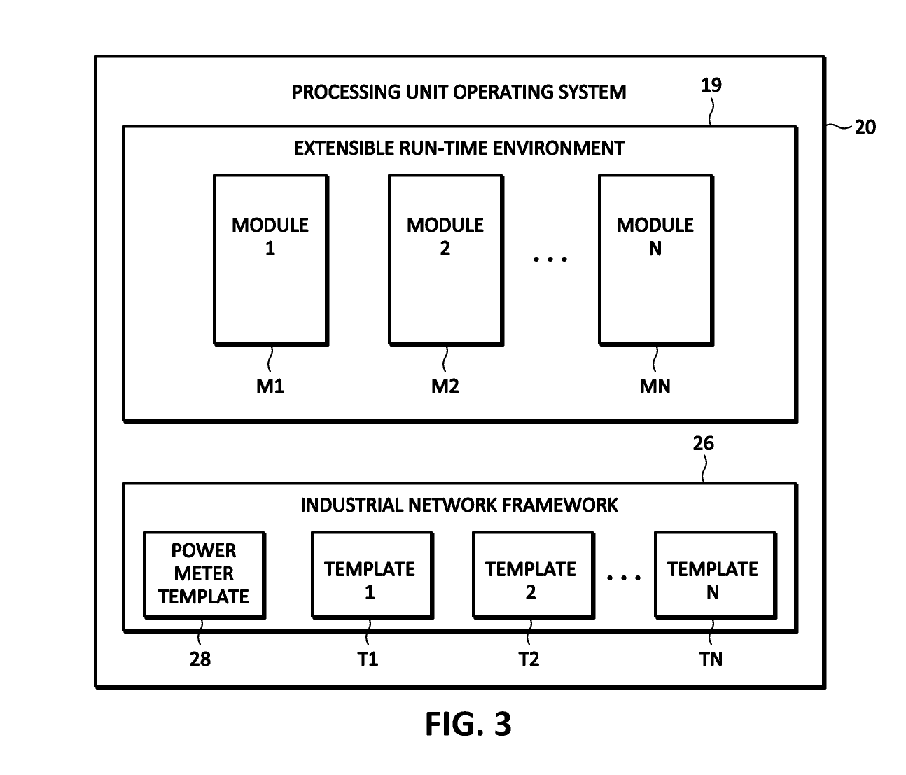

FIG. 3 illustrates an embodiment of a software platform suitable for use with an extensible power meter according to some inventive principles of this patent disclosure. The embodiment of FIG. 3 may run on the processing units of the extensible power meters of FIG. 1 or 2. The platform includes an operating system 20 that provides an extensible run-time environment 19 for add-on (extensible) functionality modules M1, M2, . . . MN (Module 1, Module 2, . . . Module N). The modules may be developed by manufacturers, systems integrators, third-party developers, end-users, etc., to enable functionality to be added to the extensible power meter beyond that already built into the operating system.

Examples of add-on module application types include processes, uploaders, loggers, computer gateway interfaces (CGIs), hybrid combinations thereof, etc. Other types of modules may enable devices coupled to a network interface to be controlled in response to commands or requests received through the same or another network interface. For example, the extensible power meter may receive a demand response signal from a utility through a general purpose computer network interface requesting load shedding due to excessive power consumption on the utility grid. Based on data from the power meter, or other power meter on the industrial network, the module may shut down a device on an industrial network to reduce power consumption.

Process type modules start at boot time and run continuously until the system shuts down. They may be used, e.g., for network servers, user-mode device drivers, proxy gateways, VPN gateways, etc. Other examples of applications that may be implemented with built-in or user-developed process type modules include filtering functions, data clean-up, data trimming, and peak-valley determination.

Uploaders send or export data collected by the extensible power meter to a database server. They may synchronize configuration files between the extensible power meter and a remote server, thereby allowing remote management and monitoring.

Loggers may be executed periodically at a data logging interval selected by a user. A logger samples data from one or more industrial devices connected through the industrial network interface, writes the data to a log file, then terminates to be re-invoked at the next log cycle.

Computer gateway interfaces may contain static HTML files for online documentation and dynamic content generated by CGI programs for configuring user developed applications.

Some example implementation details for modules are as follows, but the inventive principles are not limited to these details. Modules may contain native executables (machine code) created by assembly or compiling source code written in any suitable language for the specific processor or processors used in the processing unit. The processing unit may be implemented on a platform that includes a standard shell to enable it to execute shell scripts. A module may be stored in a compressed, read-only file system (“cramfs”) designed to store an entire directory hierarchy in a single file such as cramfs used with embedded Linux systems. A module may include any of the four application types mentioned above, i.e., processes, uploaders, loggers, computer gateway interfaces (CGIs), hybrid combinations thereof, etc. Modules may also contain any combination of these application types, and/or multiple instances of any one type. When an executable is invoked from a module, the run-time environment may be set with a process ID, primary group ID, group list, etc., and environment variables may be set or overwritten in a table or other record in a process environment.

The operating system may be implemented with any standard, customized, or fully custom system such as Linux. The operating system may include built-in run-time functionality similar to that provided by the extensible functionality modules, and may in fact be implemented as internal modules that are included with the operating system.

The operating system 20 may optionally include an industrial network framework 26 that provides an environment for add-on templates T1, T2, . . . TN (Template 1, Template 2, . . . Template N) that enable the extensible power meter to communicate with devices through the industrial network interface 12. The framework supports network commands such as read coils, input and holding registers. Some standardized templates may be included with the operating system to enable communications with known devices, while others may be developed by manufacturers, systems integrators, third-party developers, end-users, etc., to support communications with new or unknown devices.

A special template 28 may be included to communicate with the power meter 18 if the power meter is interfaced to the processing unit 17 through an internal extension of the industrial network interface 12 or a separate internal industrial network interface.

Although the network framework is shown in the context of an industrial network, a similar type of network framework may be implemented for a general purpose computer network according to the inventive principles of this patent disclosure.

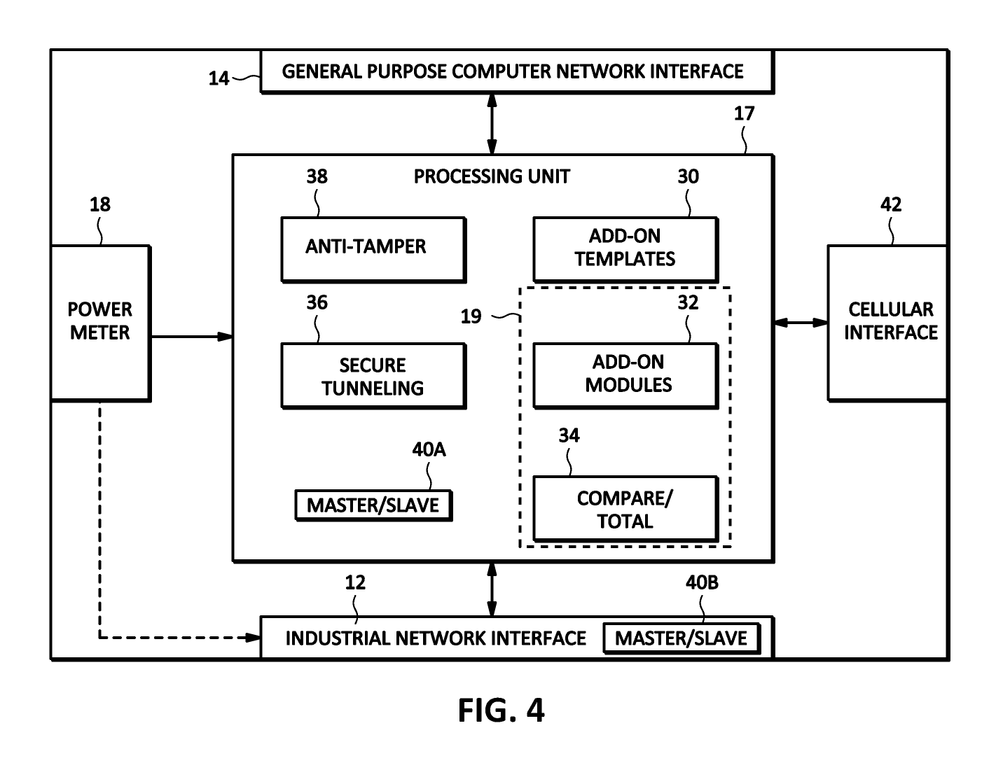

FIG. 4 illustrates another embodiment of an extensible power meter according to some inventive principles of this patent disclosure. The embodiment of FIG. 4 is similar to that of FIG. 2 but includes additional functionality including in the processing unit 17 and elsewhere.

The processing unit 17 operates an extensible run-time environment 19 to run add-on modules such as modules 32 and 34.

The processing unit 17 may include functionality 30 to run add-on templates such as those described above with respect to FIG. 3.

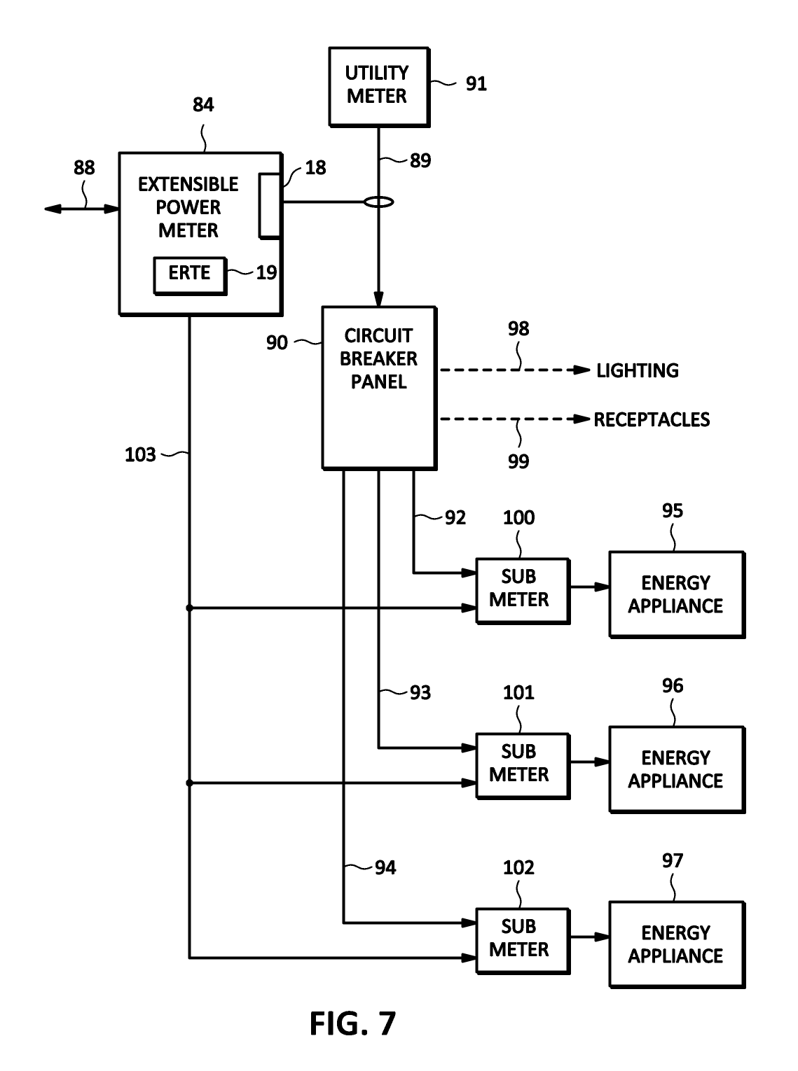

The processing unit 17 may include functionality 34 to compare data from the power meter 18 to power data received through the industrial network interface 12 or through the general purpose computer network interface 14. For example, a measurement of power from the power meter 18 may be compared to the total of power measurements from multiple power meters connected to the industrial network interface 12 as described below with respect to FIG. 7. Although the comparison and/or totalizing functionality 34 is shown as an add-on module 34, it may also be implemented as internal functionality in the processing unit.

The processing unit 17 may include functionality 36 to establish a secure tunnel through the general purpose computer network interface 14. Some or all of this functionality may also be included in the network interface 14 depending, e.g., on the how much of the tunneling is implemented as hardware versus software.

The processing unit 17 may include functionality 38 to prevent, detect, and/or report tampering with the electronic assembly. For example, the assembly may include a set of contacts that open or close when the enclosure in which the assembly is housed is opened. The actuation of the contacts may disable the extensible power meter or report a tampering event to a central control facility through the computer network interface 14.

Functionality 40A and/or 40B may be included in the processing unit 17 and/or the industrial network interface 12 to enable the extensible power meter to be configured as either a master or a slave device on the industrial network. This may be beneficial to add metering and extensible power meter functionality to a facility such as an automated factory or natural resource extraction location in which an industrial control network such as a Modbus network is already set up with a master device in place. By configuring an extensible power meter with power meter as a slave device, the metering functionality may be added with minimal disruption and reconfiguration of the existing network.

Any of the functionality described herein may be implemented with analog and/or digital hardware, software, firmware, etc., or any suitable combination thereof. As with the embodiment of FIG. 2, the power meter 18 of FIG. 4 may be interfaced directly to the processing unit 17 as shown with the solid line in FIG. 4, through the industrial network interface 12 as shown by the dashed line, or in any other suitable manner.

The embodiment of FIG. 4 may also include a cellular communication interface 42 to enable data that has been logged from the power meter 18 or through the industrial network interface 12 to be uploaded to a central data reporting and processing location. For example, the cellular communication interface 42 may implement a cellular mobile phone technology such as Code Division Multiple Access (CDMA), Global System for Mobile Communications (GSM), Advanced Mobile Phone System (AMPS), or any other suitable radio technology. The cellular communication interface 42 may be included in addition to, or instead of, the computer network interface 14 as all or part of the front end interface of the extensible power meter.

As distributed generation (DG) of electric power becomes more common, so does the need for localized power metering. For example, renewable energy sources such as solar, wind, wave, etc., tend to be connected to utility grids at widely distributed locations. Operators of these distributed generation assets are paid feed-in tariffs based on the amount of energy generated, and therefore, the metering systems must be secure and tamper-resistant. An advantage of the inventive principles of this patent disclosure is that they enable the implementation of secure locally distributed metering as shown in FIG. 4.

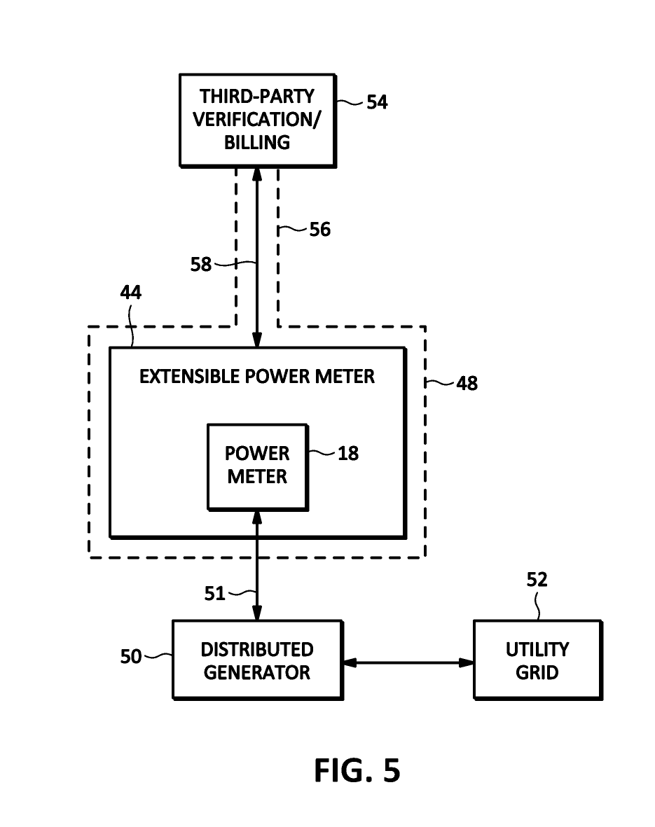

FIG. 5 illustrates an embodiment of an extensible power meter configured to provide secure anti-tamper metering according to some inventive principles of this patent disclosure. In the embodiment of FIG. 5, an extensible power meter assembly 44 includes a power meter 18 included in the same electronic assembly with a processing unit that runs an extensible run-time environment. The assembly is protected by anti-tamper functionality 48 which may include a tamper-resistant enclosure designed to prevent intrusion, and/or a tamper-detection sensor that senses and reports any attempt to tamper with the system.

The power meter 18 is coupled to a distributed generator 50 through an industrial network 51 to measure the amount of energy the generator feeds into a local utility grid 52. The data from the power meter is logged at the assembly 44 and uploaded to a third-party 54 through a secure tunnel 56 established on a general purpose computer network 58. The third-party 54 performs data verification and/or billing based on the uploaded data. Thus, the secure tunnel 56 and anti-tamper functionality 48 form a protective construct that may ensure the integrity of the metering data on which the revenue stream for the distributed generator 50 depends.

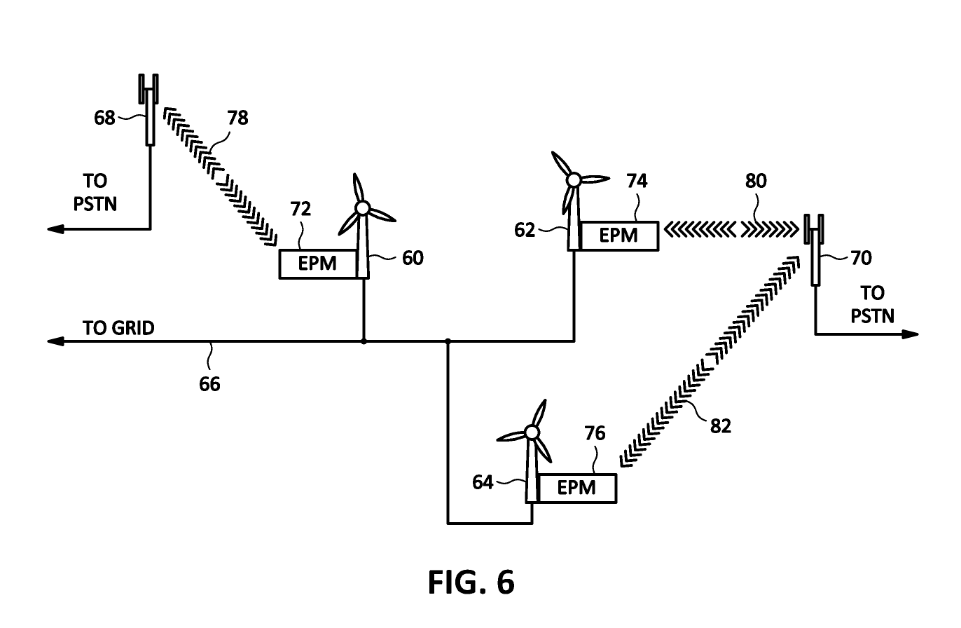

FIG. 6 illustrates an embodiment of a power generation system utilizing cellular communication technology according to some inventive principles of this patent disclosure. In the embodiment of FIG. 6, distributed generation power sources 60, 62 and 64 are located in remote locations and tied into a utility grid through a transmission line 66. In this example the power sources are wind turbines, but in other embodiments they could be other renewable power sources such as solar farms, hydroelectric or geothermal energy sources, or nonrenewable sources as well.

Although the transmission line 66 provides a connection to the grid, the area lacks a conventional data infrastructure such as wired or fiber optic internet access. However, cellular phone towers 68 and 70 are available in the area and provide access to the public switched telephone network (PSTN). Thus, extensible power meters (EPM) 72, 74 and 76 having cellular communication interfaces may be installed at power sources 60, 62 and 64, respectively, to log and upload metering data through cellular radio connections 78, 80 and 82 to one or more third party verifiers/billers through the public switched telephone network to calculate the cost of the energy produced. This provides a convenient, low-cost, easy to install metering infrastructure. Moreover, it can be combined with the anti-tamper and secure tunneling techniques illustrated with respect to FIG. 4 to provide a secure billing infrastructure.

FIG. 7 illustrates an embodiment of a system with an extensible power meter arranged for comparison, verification, etc., of readings from multiple power meters according to some inventive principles of this patent disclosure. The embodiment of FIG. 7 includes an extensible power meter assembly 84 that includes a power meter 18 included in the same electronic assembly with a processing unit that runs an extensible run-time environment. The power meter 18 is coupled to a feeder circuit 89 that feeds a circuit breaker panel 90 from a utility power meter 91. Branch circuits 92, 93 and 94 provide power to energy appliances 95, 96 and 97. Optional branch circuits 98 and 99 provide power to lights and wall receptacles. Network sub-meters 100, 101 and 102 monitor the power flowing through branch circuits 92, 93 and 94, respectively, and are interfaced to the extensible power meter assembly 84 through an RS485/Modbus network 103. The extensible power meter assembly 84 communicates with a building automation system, gateway, or other systems through a communication network 88.

Add-on modules for the extensible run-time environment 19 may be developed to perform numerous functions in the system of FIG. 7. For example, one embodiment of a module may calculate the total power measured by the multiple branch circuit sub-meters 100, 101 and 102 and compare the total to the measurements from the power meter 18 on the feeder circuit, thereby verifying the combined accuracy of the sub-meters, detect power leakage or theft, etc.

Another embodiment of a module may simply verify the accuracy of the utility meter 91 using the power meter 18.

Yet another embodiment of a module may calculate the total power measured by the multiple branch circuit sub-meters 100, 101 and 102 and subtract the total from the measurements from the power meter 18 on the feeder circuit to determine the power consumed be the optional branch circuits 98 and 99. This type of arrangement may be useful, for example, in a system in which the branch circuit sub-meters 100, 101 and 102 measure the power consumed by individual tenants in a building, and the optional branch circuits 98 and 99 serve common areas in the building.

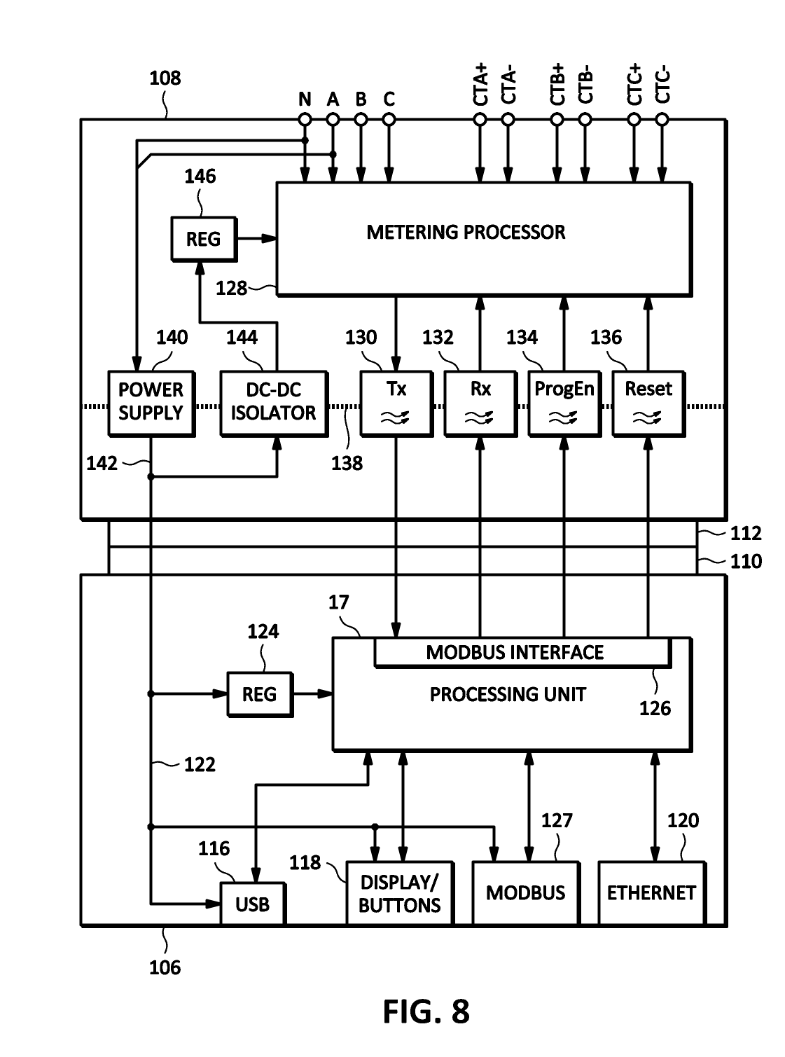

FIG. 8 illustrates an exemplary embodiment of an extensible power meter according to some inventive principles of this patent disclosure. The embodiment of FIG. 8 includes a main section 106 and a meter section 108. The main and meter sections may each be fabricated, for example, on its own circuit board and connected through headers 110 and 112 on the main and meter sections, respectively.

The meter section 108 is line-powered, and also provides power to the main section 106, thereby eliminating the need for a dedicated power supply for the main section. In this example, the meter section is line powered from the same AC power lines that the meter section is monitoring, but in other embodiments, the line power may be supplied by separate AC connections as described in more detail below. As used herein, line powered refers to a system having built-in functionality to convert AC power to the DC power needed to operate the meter without the use of an external DC power supply.

The main section 106 includes a processing unit 17 based on an ARM microprocessor architecture, but any other suitable processor architecture may be utilized. The processing unit is interfaced to external systems and operators through a USB port 116, LCD display and pushbuttons 118 and an Ethernet port 120. A 5 volt power supply bus 122, which is obtained from the meter section 108 through header 110, supplies power directly to the USB port 116 and the LCD display and pushbuttons 118. The 5 volt supply is dropped to 3.3 volts through regulator 124 to operate the processing unit 17. The processing unit is interfaced to the meter section 108 through an RS485 port 126 configured to operate at 3.3 volts and run the Modbus protocol. A second RS485 port 127 operates at 5 volts and provides and runs the Modbus protocol to interface the extensible power meter to external devices. Alternatively, 3.3 volt RS485 port 126 may be omitted and the meter section 108 may be interfaced to the 5 volt RS485 port 127.

The processing unit 17 runs the operating system including an extensible run-time environment and optionally an industrial network framework such as that described above with respect to FIG. 3.

The meter section 108 includes terminals N, A, B and C to provide voltage sensing connections to the neutral conductor and the three phase conductors, respectively, of a three-phase power system. Terminals CTA+/−, CTB+/− and CTC+/− provide connections to current transformers or other current sensing devices for each of the three power phases. The voltage and current sensing inputs are applied to a metering processor 128 which may be implemented, for example, with an NXP 2131 Arm? Processor or any other suitable processor having A/D inputs. The metering processor is isolated from the processing unit 17 in the main section 106 through opto-isolators 130, 132, 134 and 136 which couple Tx, Rx, ProgEn and Reset signals, respectively, from the metering processor 128 to the processing unit 17 across an isolation barrier 138. A power supply 140 converts the AC input obtained at voltage sense terminals N and A to a 5 volt DC power supply bus 142 which is coupled to the power supply bus 122 on the main section 106 through headers 110 and 112. A 5 volt DC-DC isolator 144 transfers power from the power supply bus 142 across the isolation barrier 138 where it is dropped down to 3.3 volts by regulator 146 for use by the metering processor 128. In this example, the AC power is taken from the N and A terminals, but in other embodiments, the AC power maybe obtained across any other suitable combination of the neutral and phase conductors N, A, B and C.

The architecture described in FIG. 8 enables the metering section 108 to be implemented as a separate circuit board that may be mounted in a piggy-back configuration to the main section 106, thereby allowing the metering functionality to be added as an optional feature to an existing extensible power meter design with a physical modification of the addition of the header 110. Thus, the metering functionality may be implemented quickly, conveniently and easily, at low cost and with minimal development effort by utilizing an existing extensible power meter design.

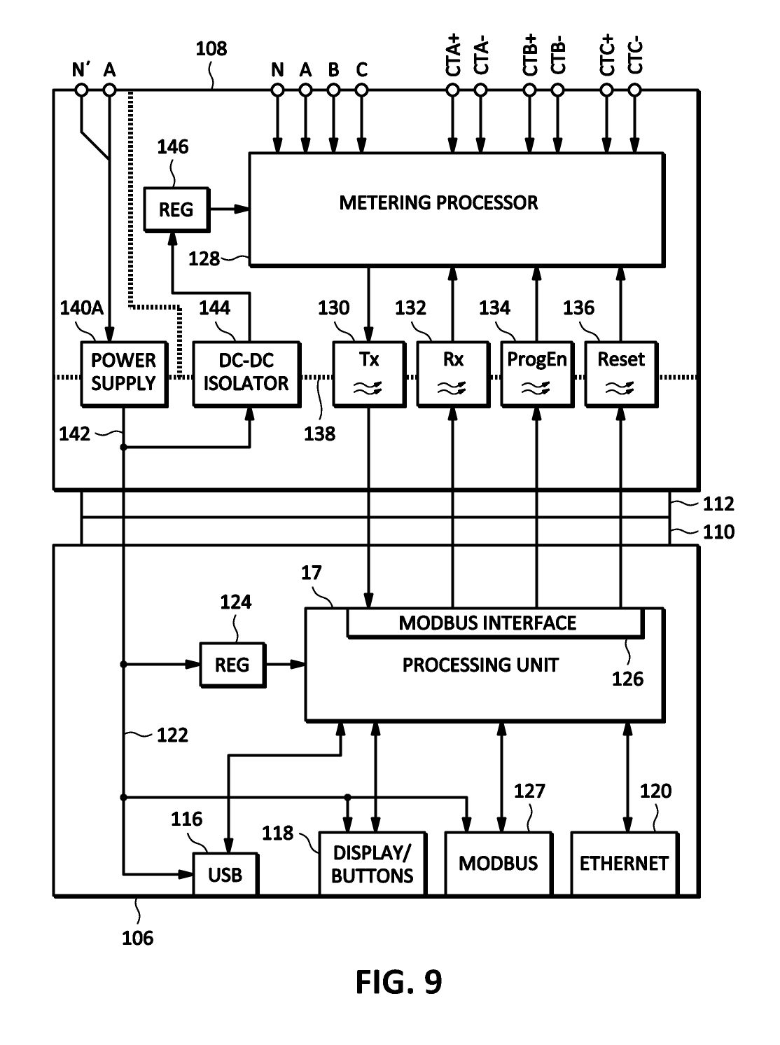

FIG. 9 illustrates another exemplary embodiment of an extensible power meter according to some inventive principles of this patent disclosure. The embodiment of FIG. 9 is similar to the embodiment of FIG. 8, but the power supply 140A obtains line power from an AC source that is separate from the AC power lines that the meter section is monitoring. In this example, the line power is obtained from a single phase AC circuit including neutral and line conductors N′ and L, respectively, which may provide, e.g., 120-277 VAC, whereas the neutral and phase terminals being monitored N, A, B and C may carry 120-480 VAC, three phase. Alternatively, fewer of the terminals N, A, B and C may be used to monitor single phase power.

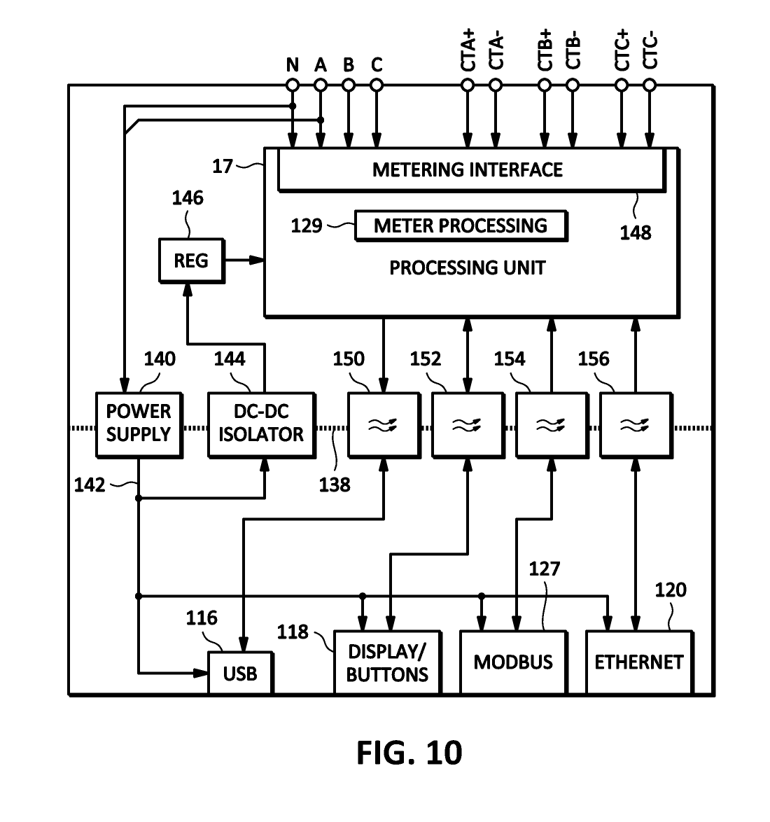

FIG. 10 illustrates another exemplary embodiment of an extensible power meter according to some inventive principles of this patent disclosure. The embodiment of FIG. 10 is similar to the embodiment of FIG. 8, but the metering processing functions 129 are integrated into the processing unit 17 which runs the operating system including an extensible run-time environment and optionally an industrial network framework such as that described above with respect to FIG. 3. Such an embodiment may enable the system to be implemented with a single circuit board, thereby reducing the manufacturing cost, improving reliability, decreasing the physical size of the system, etc.

In this embodiment, the processing unit 17 is referenced to the AC power lines N, A, B and C through a metering interface 148, so optical isolators 150, 152, 154 and 156 are provided between the processing unit 17 and the USB port 116, LCD display and pushbuttons 118 and Ethernet port 120, respectively. In other embodiments, the isolation may be moved to the metering interface 148.

The inventive principles of this patent disclosure have been described above with reference to some specific example embodiments, but these embodiments can be modified in arrangement and detail without departing from the inventive concepts. Such changes and modifications are considered to fall within the scope of the following claims.

1. An electronic assembly comprising:
a power meter;
a network interface; and
a processing unit to log data received from the power meter and upload the data through the network interface;
wherein the processing unit operates an extensible run-time environment for add-on software modules.

2. The electronic assembly of claim 1 wherein the processing unit includes functionality to establish a secure tunnel through the network interface.

3. The electronic assembly of claim 1 wherein the assembly is protected against tampering.

4. The electronic assembly of claim 1 wherein the power meter comprises a line-powered meter.

5. The electronic assembly of claim 1 further comprising an industrial network interface coupled to the processing unit.

6. The electronic assembly of claim 5 wherein the industrial network interface is capable of being configured as a master or a slave.

7. The electronic assembly of claim 5 wherein the processing unit includes functionality to compare data from the power meter to power data received through the industrial network interface.

8. The electronic assembly of claim 5 wherein the processing unit includes functionality to run templates for interfacing the processing unit to industrial devices through the network interface.

9. An electronic assembly comprising:
a meter interface;
a network interface; and
a processing unit to perform power calculations on signals received at the meter interface, log meter data from the power calculations, and upload the meter data through the network interface;
wherein the processing unit operates an extensible run-time environment for add-on software modules.

10. The electronic assembly of claim 9 further comprising an industrial network interface coupled to the processing unit.

11. The electronic assembly of claim 9 wherein the processing unit includes functionality to log additional data received through the industrial network interface and upload the additional data through the network interface.

12. A method comprising:
interfacing an electrical apparatus to an electronic assembly through a metering interface on the electronic assembly;
interfacing the electronic assembly to a communication network through a network interface on the electronic assembly;
performing metering calculations at the electronic assembly on signals received at the metering interface;
logging data from the metering calculations at the electronic assembly;
uploading the logged data through the network interface; and
operating an extensible run-time environment for add-on software modules at the electronic assembly.

13. The method of claim 12:
wherein the electrical apparatus comprises a circuit fed by a utility meter; and
the method further comprises verifying the utility meter with data from the metering calculations.

14. The method of claim 12 wherein the method further comprises interfacing the electronic assembly to one or more networked power meters.

15. The method of claim 14 wherein the method further comprises comparing data from the metering calculations to data from the one or more networked power meters.

16. The method of claim 15 wherein:
the electrical apparatus comprises a first circuit; and
the one or more networked power meters are arranged to measure power on one or more additional circuits fed by the first circuit.

17. The method of claim 16 wherein:
the one or more networked power meters include at least two networked power meters arranged to measure power on at least two additional circuits fed by the first circuit; and
the method further comprises totaling the power measured by the at least two networked power meters.

18. The method of claim 12 further comprising protecting the electronic assembly against tampering.

19. The method of claim 18 further comprising performing third-party verification or billing on the data uploaded through the network interface.

20. The method of claim 19 wherein the electrical apparatus comprises a distributed generator.

21. A method comprising:
interfacing an electrical apparatus to an electronic assembly through a metering interface on the electronic assembly;
interfacing the electronic assembly to a cellular communication network;
performing metering calculations at the electronic assembly on signals received at the metering interface;
logging data from the metering calculations at the electronic assembly; and
uploading the logged data through the cellular communication network.

22. The method of claim 21 further comprising operating an extensible run-time environment for add-on software modules at the electronic assembly.

23. The method of claim 21 wherein the cellular communication network comprises a mobile phone network.

24. The method of claim 21 wherein:
the electrical apparatus comprises an electric generator powered by a renewable energy source; and
the uploaded data is used to calculate a cost of the electricity produced.
